(19) United States
(12) Patent Application Publication
(10) Pub. No.: US 2009/0246698 A1
(43) Pub. Date: Oct. 1, 2009

(54) METHODS FOR IMAGING AND PROCESSING NEGATIVE-WORKING IMAGEABLE ELEMENTS

(76) Inventors: Kevin B. Ray, Fort Collins, CO (US); Joanne Ray, Fort Collins, CO (US); Lee J. Korionoff, Fort Collins, CO (US)

Correspondence Address: Andrew J. Anderson;Patent Legal Staff, Eastman Kodak Company, 343 State Street, Rochester, NY, 14650-2201, US

(21) Appl. No.: 12/057,673

(22) Filed: Mar. 28, 2008

(51) Int. Cl. G03F 7/12

(52) U.S. Cl. 430/302

(57) ABSTRACT

An imaged and developed element, such as a lithographic printing plate, is provided by infrared radiation imaging of a negative-working imageable element having an outermost imageable layer that includes an acid generating compound that generates acid upon exposure to imaging infrared radiation, an infrared radiation absorbing compound, an acid activatable crosslinking agent that has acid activatable reactive groups, and a polymeric binder that is capable of undergoing an acid-catalyzed condensation reaction with the crosslinking agent. The imaged element is heated at from about 120 to about 150° C. for up to two minutes, and then developed with a single processing solution to remove only the non-exposed regions and to provide a protective layer prior to lithographic printing.

### FIELD OF THE INVENTION

This invention relates to a method of imaging and processing negative-working imageable elements such as negative-working lithographic printing plate precursors. The invention uses a single processing solution that both develops and protects the imaged surface before the imaged element is used in lithographic printing.

### BACKGROUND OF THE INVENTION

Radiation-sensitive compositions are routinely used in the preparation of imageable materials including lithographic printing plate precursors. Such compositions generally include a radiation-sensitive component, an initiator system, and a binder, each of which has been the focus of research to provide various improvements in physical properties, imaging performance, and image characteristics.

Recent developments in the field of printing plate precursors concern the use of radiation-sensitive compositions that can be imaged by means of lasers or laser diodes, and more particularly, that can be imaged and/or developed on-press. Laser exposure does not require conventional silver halide graphic arts films as intermediate information carriers (or “masks”) since the lasers can be controlled directly by computers. High-performance lasers or laser-diodes that are used in commercially-available image-setters generally emit radiation having a wavelength of at least 700 nm, and thus the radiation-sensitive compositions are required to be sensitive in the near-infrared or infrared region of the electromagnetic spectrum. However, other useful radiation-sensitive compositions are designed for imaging with ultraviolet or visible radiation.

There are two possible ways of using radiation-sensitive compositions for the preparation of printing plates. For negative-working printing plates, exposed regions in the radiation-sensitive compositions are hardened and unexposed regions are washed off during development. For positive-working printing plates, the exposed regions are dissolved in a developer and the unexposed regions become an image.

Various radiation-sensitive compositions that can be used to generate free radicals upon thermal imaging and imageable elements containing same are described in numerous publications. Such negative-working imageable elements are generally processed after imaging using aqueous high pH developers. Development using gums is described for example, in EP Publications 1,751,625 (Van Damme et al. published as WO 2005/111727) 1,788,429 (Loccufier et al. et al.), 1,788,430 (Williamson et al.), 1,788,431 (Van Damme et al.), 1,788,434 (Van Damme et al.), 1,788,441 (Van Damme), 1,788,442 (Van Damme), 1,788,443 (Van Damme), 1,788,444 (Van Damme), and 1,788,450 (Van Damme), and WO 2007/057442 (Gries et al.). The imageable elements used in these references have either a protective oxygen-barrier overcoat, an intermediate layer between the substrate and imageable layer, or both.

UV-sensitive negative-working imageable elements that contain acid-generating chemistry are also known, for example as described in U.S. Pat. No. 7,045,269 (Collins et al.). U.S. Pat. No. 7,060,409 (Tao et al.) describes IR-sensitive negative-working imageable elements that contain acid-generating chemistry. Known alkaline developers are used to process the imaged elements to prepare lithographic printing plates.

Simple processing (development) of imaged elements has become a goal of workers in the lithographic art. For example, copending and commonly assigned U.S. Ser. No. 11/872,772 that was filed Oct. 16, 2007 by K. Ray, Tao, Miller, Clark, and Roth) describes negative-working imageable elements that are sensitive to infrared radiation and can be simply processed (developed and “gummed”) using finishing gum solutions without the need for a conventional alkaline developer. This reduces the amount of processing equipment that is needed, costs, and consumption of processing solution.

In addition, copending and commonly assigned U.S. Ser. No. 11/947,817 (filed Dec. 4, 2007 by K. Ray, Tao, and Clark) describes the use of gums to develop imaged UV-sensitive, negative-working imageable elements that contain specific nonpolymeric diamide additives.

Copending and commonly assigned U.S. Ser. No. 12/017,408 (filed Jan. 22, 2008 by K. Ray and Kitson) describes the use of a single non-silicate processing solution to both develop and protect images in imaged positive-working lithographic printing plate precursors.

In addition, copending and commonly assigned U.S. Ser. No. 12/019,681 filed Jan. 25, 2008 by K. Ray and Kitson) describes the use of a “fresh” sample of processing solution to provide images in either positive-working or negative-working imageable elements.

U.S. Pat. No. 4,179,208 (Martino) describes a processing machine that uses an alkaline developer that is modified by the addition of a small amount of “gum”, and the developer is re-used or replenished but there are no details about the composition of this modified developer.

### PROBLEM TO BE SOLVED

Known processing methods using traditional alkaline development followed by gumming have a number of problems that are addressed by the use of “simple” processing methods using a gum-like processing solution. There is a need to provide “simple” processing methods with negative-working lithographic printing plate precursors having acid-generating chemistries that avoid the noted problems. There is also a desire to use a simple processing method with acid-catalyzed negative-working imageable elements that are manufactured without the typical oxygen barrier topcoat.

### SUMMARY OF THE INVENTION

This invention provides a method of making an image comprising:

A) using a laser providing infrared radiation, imagewise exposing a negative-working imageable element comprising a substrate having directly thereon an outermost negative-working imageable layer to provide exposed and non-exposed regions,

the outermost negative-working imageable layer comprising:

an acid generating compound that generates acid upon exposure to imaging infrared radiation,

an infrared radiation absorbing compound,

an acid activatable crosslinking agent that has at least two acid-activatable reactive groups, and

a polymeric binder that is capable of undergoing an acid-catalyzed condensation reaction with the crosslinking agent,

B) heating the imagewise exposed element at from about 120 to about 150° C. for up to two minutes, and

C) applying a single processing solution having a pH of from about 6 to about 11 to the imaged and heated element both: (1) to remove predominantly only the non-exposed regions, and (2) to provide a protective coating over all of the non-exposed and exposed regions of the resulting lithographic printing plate,

provided that when at least 40% of the acid activatable reactive groups are hydroxymethyl groups, the single processing solution comprises up to 8 weight % of a water-miscible organic solvent.

This invention also provides a method of lithographic printing comprising:

A) using a laser providing infrared radiation, imagewise exposing a negative-working lithographic printing plate precursor comprising a hydrophilic aluminum-containing substrate having directly thereon an outermost negative-working imageable layer to provide exposed and non-exposed regions,

the outermost negative-working imageable layer comprising:

an acid generating compound that generates acid upon exposure to imaging infrared radiation,

an infrared radiation absorbing compound,

an acid activatable crosslinking agent that has at least two acid-activatable reactive groups that are bonded to an aromatic ring, wherein at least 50% of the reactive groups are alkoxymethyl groups, and

a polymeric binder that is capable of undergoing an acid-catalyzed condensation reaction with the crosslinking agent,

B) heating the imagewise exposed element at from about 120 to about 150° C. for up to two minutes,

C) applying a single processing solution having a pH of from about 6 to about 11 to the imaged and heated precursor both: (1) to remove predominantly only the non-exposed regions, and (2) to provide a protective coating over all of the non-exposed and exposed regions of the resulting lithographic printing plate,

provided that when at least 40% of the acid activatable reactive groups are hydroxymethyl groups, the single processing solution comprises up to 8 weight % of a water-miscible organic solvent,

D) mechanically removing excess single processing solution from the imaged and heated lithographic printing plate, with optional drying, and

E) contacting the lithographic printing plate with a lithographic printing ink, fountain solution, or both.

The substrate can be an aluminum-containing substrate having a hydrophilic surface upon which the imageable layer is disposed, and the imaged and processed element can be a lithographic printing plate.

With the present invention, acid-catalyzed negative-working imageable elements can be imaged and then processed without the use of high pH, toxic, and corrosive developers. Instead, processing can be carried out using simple processing solutions that both develop the image and protect the developed surface. The processed elements do not require an oxygen barrier overcoat layer or an intermediate layer to adhere the substrate to the outermost imageable layer. Thus, the imageable elements used in this invention are simpler in construction without a loss in imaging and developing properties.

### DETAILED DESCRIPTION OF THE INVENTION

### Definitions

Unless the context indicates otherwise, when used herein, the terms “imageable element”, “lithographic printing plate precursor”, and “printing plate precursor” are meant to be references to embodiments useful in the present invention.

In addition, unless the context indicates otherwise, the various components described herein such as “primary polymeric binder”, “acid generating compound”, “acid activatable crosslinking agent”, “infrared radiation absorbing compound”, and similar terms also refer to mixtures of such components. Thus, the use of the articles “a”, “an”, and “the” is not necessarily meant to refer to only a single component.

Moreover, unless otherwise indicated, percentages refer to percents by dry weight, for example, weight % based on total solids or dry layer composition.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

“Graft” polymer or copolymer refers to a polymer having a side chain that has a molecular weight of at least 200.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Imageable Layers

The imageable elements include an infrared (IR) radiation-sensitive imaging composition disposed on a suitable substrate to form an imageable layer. The imageable elements may have any utility wherever there is a need for an applied coating that is crosslinkable using suitable infrared radiation, and particularly where it is desired to remove non-exposed regions of the coating instead of exposed regions. The IR radiation-sensitive compositions can be used to prepare an imageable layer in imageable elements such as printed circuit boards for integrated circuits, microoptical devices, color filters, photomasks, and printed forms such as lithographic printing plate precursors that are defined in more detail below.

While some details of such imageable layers are provided in this disclosure, further details can be obtained from U.S. Pat. No. 7,060,409 (noted above) and the references cited therein in Col. 2, for example, all of which are incorporated herein by reference.

The imageable layer includes one or more acid generating compounds that generate an acid upon exposure to infrared radiation. Such compounds are generally precursors that form Brönsted acids by thermally initiated decomposition. Such compounds can be non-ionic or ionic in nature.

Non-ionic acid generators include, for example, haloalkyl-substituted s-triazines, that are described, for example, in U.S. Pat. No. 3,779,778 (Smith). Haloalkyl-substituted s-triazines are s-triazines substituted with one to three CX₃ groups in which X is bromo or chloro. Examples of such compounds include but are not limited to, 2-phenyl-4,6-bis(trichloromethyl)-s-triazine, 2,4,6-tris(trichloromethyl)-s-triazine, 2-methyl-4,6-bis(trichloromethyl)-s-triazine, 2-styryl-4,6-bis(trichloromethyl)-s-triazine, 2-(p-methoxystyryl)-4,6-bis(trichloromethyl)-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, and 2-[4-(2-ethoxyethyl)-naphtho-1-yl]-4,6-bis-trichloromethyl-s-triazine.

Ionic acid generators include, for example, onium salts in which the onium cation is iodonium, sulphonium, phosphonium, oxysulphoxonium, oxysulphonium, sulphoxonium, ammonium, diazonium, selenonium, or arsonium, and the anion is a chloride, bromide, or a non-nucleophilic anion such as tetrafluoroborate, hexafluorophosphate, hexafluoroarsenate, hexafluoroantimonate, triflate, tetrakis(pentafluoro-phenyl)borate, pentafluoroethyl sulfonate, p-methyl-benzyl sulfonate, ethyl sulfonate, trifluoromethyl acetate, and pentafluoroethyl acetate. Typical onium salts include, for example, diphenyl iodonium chloride, diphenyl iodonium hexafluorophosphate, diphenyl iodonium hexafluoroantimonate, 4,4′-dicumyl iodonium chloride, 4,4′-dicumyl iodonium hexafluorophosphate, N-methoxy-α-picolinium-p-toluene sulfonate, 4-methoxybenzene-diazonium tetrafluoroborate, 4,4′-bis-dodecylphenyl iodonium-hexafluorophosphate, 2-cyanoethyl-triphenylphosphonium chloride, bis-[4-diphenylsulfoniophenyl]sulfide-bis-hexafluorophosphate, bis-4-dodecylphenyliodonium hexafluoroantimonate, triphenyl sulfonium hexafluoroantimonate, triphenyl sulfonium tetrafluoroborate, 2-methoxy-4-aminophenyl diazonium hexafluorophosphate, phenoxyphenyl diazonium hexafluoroantimonate, and anilinophenyl diazonium hexafluoroantimonate.

Particularly useful ionic acid generators include iodonium, sulfonium, and diazonium salts in which the anion is an organic sulfate or thiosulfate, such as, for example, methyl sulfate or thiosulfate, ethyl sulfate or thiosulfate, hexyl sulfate or thiosulfate, octyl sulfate or thiosulfate, decyl sulfate or thiosulfate, dodecyl sulfate and thiosulfate, trifluoromethyl sulfate or thiosulfate, benzyl sulfate or thiosulfate, pentafluorophenyl sulfate and thiosulfate. Such ionic acid generators can be prepared by mixing an onium salt containing the desired anion either in water or in an aqueous solvent including a hydrophilic solvent such as an alcohol or propylene glycol methyl ether.

The acid generating compound is generally present in the imageable layer composition in an amount of from about 1 to about 50 weight % and typically from about 1.5 to about 25 weight %, based on total dry composition (or imageable layer) weight.

The imageable layer composition is generally responsive to infrared imaging radiation corresponding to the spectral range of at least 700 nm and up to and including 1400 nm (typically from about 750 to about 1200 nm). This sensitivity is provided by the presence of one or more infrared radiation absorbing compounds, chromophores, or sensitizers, that absorb imaging radiation, or sensitize the composition to imaging infrared radiation having a of from about 700 nm and up to and including 1400 nm, and typically from about 700 to about 1200 nm.

Useful IR radiation absorbing chromophores include various IR-sensitive dyes (“IR dyes”). Examples of suitable IR dyes comprising the desired chromophore include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. Nos. 5,208,135 (Patel et al.), 6,153,356 (Urano et al.), 6,264,920 (Achilefu et al.), 6,309,792 (Hauck et al.), and 6,787,281 (Tao et al.), and EP 1,182,033A2 (noted above). Infrared radiation absorbing N-alkylsulfate cyanine dyes are described for example in U.S. Pat. No. 7,018,775 (Tao).

A general description of one class of suitable cyanine dyes is shown by the formula in paragraph [0026] of WO 2004/101280 (Munnelly et al.), incorporated herein by reference, and a useful IR absorbing compound is identified below with the Examples.

In addition to low molecular weight IR-absorbing dyes, IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. Nos. 6,309,792 (Hauck et al.), 6,264,920 (Achilefu et al.), 6,153,356 (Urano et al.), 5,496,903 (Watanate et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S. Pat. No. 4,973,572 (DeBoer).

Other useful IR-sensitive dyes having the desired chromophore can be defined by the following Structure DYE-1:

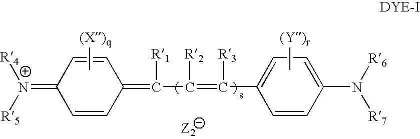

wherein R₁′, R₂′, and R₃′ each independently represents hydrogen, or a halo, cyano, substituted or unsubstituted alkoxy (having 1 to 8 carbon atoms, both linear and branched alkoxy groups), substituted or unsubstituted aryloxy (having 6 to 10 carbon atoms in the carbocyclic ring), substituted or unsubstituted acyloxy (having 2 to 6 carbon atoms), carbamoyl, substituted or unsubstituted acyl, substituted or unsubstituted acylamido, substituted or unsubstituted alkylamino (having at least one carbon atom), substituted or unsubstituted carbocyclic aryl groups (having 6 to 10 carbon atoms in the aromatic ring, such as phenyl and naphthyl groups), substituted or unsubstituted alkyl groups (having 1 to 8 carbon atoms, both linear and branched isomers), substituted or unsubstituted arylamino, or substituted or unsubstituted heteroaryl (having at least 5 carbon and heteroatoms in the ring) group. Alternatively, any two of R₁′, R₂′, and R₃′ groups may be joined together or with an adjacent aromatic ring to complete a 5- to 7-membered substituted or unsubstituted carbocyclic or heterocyclic ring.

For example, R₁′, R₂′, and R₃′ are independently hydrogen, a substituted or unsubstituted carbocyclic aryl group, and a substituted or unsubstituted heteroaryl group.

R₄′, R₅′, R₆′, and R₇′ each independently represents hydrogen, a substituted or unsubstituted alkyl group (having 1 to 10 carbon atoms), a substituted or unsubstituted cycloalkyl group (having from 4 to 6 carbon atoms in the ring), a substituted or unsubstituted aryl group (having at least 6 carbon atoms in the ring), or a substituted or unsubstituted heteroaryl group (having 5 to 10 carbon and heteroatoms in the ring).

Alternatively, R₄′ and R₅′ or R₆′ and R₇′ can be joined together to form a substituted or unsubstituted 5- to 9-membered heterocyclic ring, or R₄′, R₅′, R₆′, or R₇′ can be joined to the carbon atom of the adjacent aromatic ring at a position ortho to the position of attachment of the anilino nitrogen to form, along with the nitrogen to which they are attached, a substituted or unsubstituted 5- or 6-membered heterocyclic ring.

For example, R₄′, R₅′, R₆′, and R₇′ are independently a substituted or unsubstituted alkyl group, a substituted or unsubstituted cycloalkyl group, a substituted or unsubstituted aryl group, or R₄′ and R₅′ or R₆′ and R₇′ can be joined together to form a substituted or unsubstituted 5- to 7-membered heterocyclic ring. Also, they can be independently substituted or unsubstituted alkyl groups of 1 to 8 carbon atoms, substituted or unsubstituted phenyl groups, or R₄′ and R₅′ or R₆′ and R₇′ can be joined together to form a substituted or unsubstituted 5- to 7-membered heteroaryl group.

In the DYE 1 structure, s is 1, 2, or 3, Z₂ is a monovalent anion, X″ and Y″ are each independently R₁′ or the atoms necessary to complete a substituted or unsubstituted 5- to 7-membered fused carbocyclic or heterocyclic ring, and q and r are independently integers from 1 to 4.

For example, X″ and Y″ are independently hydrogen or the carbon and heteroatoms needed to provide a fused aryl or heteroaryl ring.

Further details of such bis(aminoaryl)pentadiene IR dyes are provided, including representative IR dyes identified as DYE 1 through DYE 17, DYE 19, and DYE 20, in U.S. Pat. No. 6,623,908 (Zheng et al.).

Some useful infrared radiation absorbing dyes have a tetraaryl pentadiene chromophore. Such chromophore generally includes a pentadiene linking group having 5 carbon atoms in the chain, to which are attached two substituted or unsubstituted aryl groups at each end of the linking group. The pentadiene linking group can also be substituted with one or more substituents in place of the hydrogen atoms, or two or more hydrogen atoms can be replaced with atoms to form a ring in the linking group as long as there are alternative carbon-carbon single bonds and carbon-carbon double bonds in the chain.

Such IR-sensitive dyes can be represented by the following Structure DYE-II:

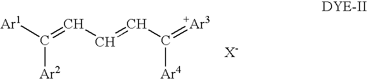

wherein Ar¹ through Ar⁴ are the same or different substituted or unsubstituted aryl groups having at least carbon atoms in the aromatic ring (such as phenyl, naphthyl, and anthryl, or other aromatic fused ring systems) wherein 1 to 3 of the aryl groups are substituted with the same or different tertiary amino group (such as in the 4-position of a phenyl group). Typically two of the aryl groups are substituted with the same or different tertiary amino group, and usually at different ends of the polymethine chain (that is, molecule). For example, Ar¹ or Ar² and Ar³ or Ar⁴ bear the tertiary amine groups. Representative amino groups include but are not limited to those substituted with substituted or unsubstituted alkyl groups having up to 10 carbon atoms or aryl groups such as dialkylamino groups (such as dimethylamino and diethylamino), diarylamino groups (such as diphenylamino), alkylarylamino groups (such as N-methylanilino), and heterocyclic groups such as pyrrolidino, morpholino, and piperidino groups. The tertiary amino group can form part of a fused ring such that one or more of Ar¹ through Ar⁴ can represent a julolidine group.

Besides the noted tertiary groups noted above, the aryl groups can be substituted with one or more substituted or unsubstituted alkyl groups having 1 to 10 carbon atoms, halo atoms (such as chloro or bromo), hydroxyl groups, thioether groups, and substituted or unsubstituted alkoxy groups having 1 to 10 carbon atoms. Substituents that contribute electron density to the conjugated system are useful. While they are not specifically shown in Structure (DYE-II), substituents or fused rings may also exist on (or as part of) the conjugated chain connecting the aryl groups.

In Structure (DYE-II), X⁻ is a suitable counterion that may be derived from a strong acid, and include such anions as ClO₄⁻, BF₄⁻, CF₃SO₃⁻, PF₆⁻, AsF₆⁻, SF₆⁻, and perfluoroethylcyclohexylsulfonate. Other cations include boron-containing anions as described above (borates), methylbenzenesulfonic acid, benzenesulfonic acid, methanesulfonic acid, p-hydroxybenzenesulfonic acid, p-chlorobenzenesulfonic acid, and halides.

Two representative IR dyes defined by Structure (DYE-II) are defined as D1 and D2 in WO 98/07574 (Patel et al.). Still other useful IR-sensitive dyes are represented by the following Structure (DYE-III):

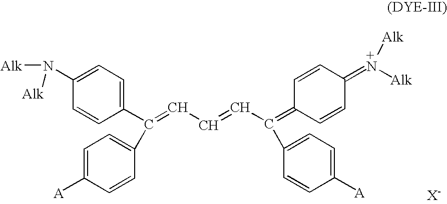

wherein “Alk” represents the same or different substituted or unsubstituted alkyl groups having 1 to 7 carbon atoms (such as substituted or unsubstituted methyl, ethyl, iso-propyl, t-butyl, n-hexyl, and benzyl), and “A” represents hydrogen or the same or different substituted or unsubstituted lower alkyl group having 1 to 3 carbon atoms (such as methyl, ethyl, n-propyl, and iso-propyl), or the same or different dialkylamino groups similar to those defined above for Structure (DYE-2), wherein such groups have the same or different alkyl groups. X⁻ is a suitable counterion as defined above for Structure (DYE-II).

Useful infrared radiation absorbing dyes can be obtained from a number of commercial sources including Showa Denko (Japan) or they can be prepared using known starting materials and procedures.

Still other useful infrared radiation absorbing compounds are copolymers can comprise covalently attached ammonium, sulfonium, phosphonium, or iodonium cations and infrared radiation absorbing cyanine anions that have two or four sulfonate or sulfate groups, or infrared radiation absorbing oxonol anions, as described for example in U.S. Pat. No. 7,049,046 (Tao et al.).

The infrared radiation absorbing compounds can be present in the IR-sensitive composition (or imageable layer) in an amount generally of at least 1% and up to and including 30% and typically at least 3 and up to and including 20%, based on total solids in the composition, that also corresponds to the total dry weight of the imageable layer. The particular amount needed for this purpose would be readily apparent to one skilled in the art, depending upon the specific compound used to provide the desired chromophore.

The imageable layer also includes an activatable crosslinking agent that has at least two acid-activatable reactive groups. These reactive groups may be bonded to an aromatic ring (such as a phenyl or naphthyl ring) or a heterocyclic ring. Mixtures of different activatable crosslinking agents can also be used, each having different acid-activatable reactive groups. The reactive groups include but are not limited to, hydroxymethyl, alkoxymethyl, epoxy, and vinyl ether groups. However at least 50% and typically at least 75% of the reactive groups in the crosslinking agents that are present in the imageable layer are alkoxymethyl groups (such as methoxymethyl, ethoxymethyl, and butoxymethyl groups). Examples include but are not limited to methylol melamine resins, resole resins, epoxidized novolac resins, and urea resins. Other examples are amino resins having at least two alkoxymethyl groups (such as alkoxymethylated melamine resins, alkoxymethylated glycolurils, and alkoxymethylated benzoguanamines). The methylol melamine resins are particularly useful. Commercial varieties of the acid activatable crosslinking agents are available from several sources including Cytec Industries (West Patterson, N.J.), Pfaltz and Bauer (Waterbury, Conn.), and TCI America (Portland, Oreg.).

The acid activatable crosslinking agents are present in an amount of from about 5 to about 70 weight % and typically from about 10 to about 65 weight %, based on the total composition (or layer) dry weight.

The imageable layer includes one or more polymeric binders that are capable of undergoing an acid-catalyzed condensation reaction with the crosslinking agent when heated to a temperature of from about 60 to about 220° C. Thus, any polymeric binder that will undergo such a reaction under the desired imaging or processing conditions may be used. Various combinations of polymeric binder and acid activatable crosslinking agent can be used in the practice of this invention. For example, such polymeric binders can have a reactive pendant group such as carboxylic acid, sulfonamide, or alkoxymethyl amide groups. These polymers generally have a weight average molecular weight of from about 2,000 to about 500,000 and typically from about 4,000 to about 300,000.

Typical polymeric binders include, for example, poly(4-hydroxystyrene/methyl methacrylate), poly(2-hydroxyethyl methacrylate/cyclohexyl methacrylate), poly(2-hydroxyethyl methacrylate/methyl methacrylate), poly(styrene/butyl methacrylate/methyl methacrylate/methacrylic acid), poly(butyl methacrylate/methacrylic acid), poly(vinylphenol/2-hydroxyethyl methacrylate), poly(styrene/n-butyl methacrylate/2-hydroxyethyl methacrylate/methacrylic acid), poly(styrene/ethyl methacrylate/2-hydroxyethyl methacrylate/methacrylic acid, poly(N-methoxymethyl methacrylamide/2-phenylethyl methacrylate/methacrylic acid), poly(2-hydroxyethyl methacrylate/cyclohexyl methacrylate/methacrylic acid), poly(N-methoxymethyl methacrylamide/2-phenylethyl methacrylate/methacrylamide/methacrylic acid), poly(N-methoxymethyl methacrylamide/styrene/butyl methacrylate/methacrylic acid), poly(N-iso-butoxymethyl acrylamide/2-hydroxyethyl methacrylate/methyl methacrylate), poly(styrene/n-butyl methacrylate/methacrylic acid/N-iso-butoxymethyl methacrylamide), and poly(methyl methacrylate/styrene/methacrylic acid. Such copolymers are disclosed for example in U.S. Pat. No. 5,919,601 (Nguyen).

The polymeric binder is generally present in the IR-sensitive composition (imageable layer) in an amount of from about 10 to about 90% and typically from about 20 to about 85%, based on the total composition or imageable layer dry weight.

The imageable layer can also include a variety of optional compounds including but not limited to, dispersing agents, humectants, biocides, plasticizers, surfactants for coatability or other properties, viscosity builders, contrast dyes or colorants to allow visualization of the written image (such as crystal violet, methyl violet, ethyl violet, Victoria Blue B, Victoria Blue R, malachite green, and brilliant green), pH adjusters, drying agents, defoamers, preservatives, antioxidants, development aids, rheology modifiers or combinations thereof, or any other addenda commonly used in the lithographic art, in conventional amounts. Useful viscosity builders include hydroxypropyl cellulose, hydroxyethyl cellulose, carboxymethyl cellulose, and poly(vinyl pyrrolidones).

### Imageable Elements

The imageable elements can be formed by suitable application of an infrared radiation-sensitive composition as described above to a suitable substrate to form an imageable layer. This substrate can be treated or coated in various ways as described below prior to application of the radiation-sensitive composition to improve hydrophilicity. Typically, there is only a single imageable layer comprising the radiation-sensitive composition that is directly applied to the substrate without any intermediate layer such as those described in EP Patent Publications described above in the Background of the Invention. If the substrate has been treated to provide improved adhesion or hydrophilicity, the applied imageable layer is disposed thereon but these treatments are not considered “intermediate layers” for the purpose of this invention.

The element does not include what is conventionally known as an overcoat (also known as an “oxygen impermeable topcoat” or “oxygen barrier layer”) disposed over the imageable layer, for example, as described in EP Patent Publications 1,788,429, 1,788,431 and 1,788,434 (all noted above) and US Patent Application Publication 2005/0266349 (noted above). Such overcoat layers predominantly comprise one or more poly(vinyl alcohol)s as the predominant polymeric binders. Thus, the imageable layer is the outermost layer of the element in the practice of this invention.

The substrate generally has a hydrophilic surface, or at least a surface that is more hydrophilic than the applied imageable layer on the imaging side. The substrate comprises a support that can be composed of any material that is conventionally used to prepare imageable elements such as lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

One useful substrate is composed of an aluminum support that may be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful hydrophilic lithographic substrate is an electrochemically grained and sulfuric acid or phosphoric acid anodized aluminum support that provides a hydrophilic surface for lithographic printing.

Sulfuric acid anodization of the aluminum support generally provides an oxide weight (coverage) on the surface of from about 1.5 to about 5 g/m² and more typically from about 3 to about 4.3 g/m². Phosphoric acid anodization generally provides an oxide weight on the surface of from about 1.5 to about 5 g/m² and more typically from about 1 to about 3 g/m². When sulfuric acid is used for anodization, higher oxide weight (at least 3 g/m²) may provide longer press life.

The aluminum support may also be treated with, for example, a silicate, dextrine, calcium zirconium fluoride, hexafluorosilicic acid, poly(vinyl phosphonic acid) (PVPA), vinyl phosphonic acid copolymer, poly[(meth)acrylic acid], or acrylic acid copolymer to increase hydrophilicity. Still further, the aluminum support may be treated with a phosphate solution that may further contain an inorganic fluoride (PF). The aluminum support can be electrochemically-grained, sulfuric acid-anodized, and treated with PVPA or PF using known procedures to improve surface hydrophilicity.

The thickness of the substrate can be varied but should be sufficient to sustain the wear from printing and thin enough to wrap around a printing form. Useful embodiments include a treated aluminum foil having a thickness of at least 100 μm and up to and including 700 μm.

The backside (non-imaging side) of the substrate may be coated with antistatic agents and/or slipping layers or a matte layer to improve handling and “feel” of the imageable element.

The substrate can also be a cylindrical surface having the imageable layer thereon, and thus be an integral part of the printing press. The use of such imaging cylinders is described for example in U.S. Pat. No. 5,713,287 (Gelbart).

An infrared radiation-sensitive composition containing the components described above can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder).

Illustrative of such manufacturing methods is mixing the acid generating compound, polymeric binder, acid activatable crosslinking agent, IR radiation absorbing compound, and any other components of the infrared radiation-sensitive composition in a suitable coating solvent including water, organic solvents [such as glycol ethers including 1-methoxypropan-2-ol, methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], or mixtures thereof, applying the resulting solution to a substrate, and removing the solvent(s) by evaporation under suitable drying conditions. Some representative coating solvents and imageable layer formulations are described in the Invention Examples below. After proper drying, the coating weight of the imageable layer is generally at least 0.1 and up to and including 5 g/m² or at least 0.5 and up to and including 3.5 g/m².

### Imaging Conditions

During use, the imageable element is exposed to a suitable source of infrared or near-infrared imaging or exposing radiation depending upon the infrared radiation absorbing compound present in the radiation-sensitive composition, at a wavelength of from about 700 to about 1500 nm. For example, imaging can be carried out using imaging or exposing radiation, such as from an infrared laser (or array of lasers) at a wavelength of at least 750 nm and up to and including about 1400 nm and typically at least 700 nm and up to and including 1200 nm. Imaging can be carried out using imaging radiation at multiple wavelengths at the same time if desired.

The laser used to expose the imageable element is usually a diode laser (or array of lasers), because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of at least 800 nm and up to and including 850 nm or at least 1060 and up to and including 1120 nm.

The imaging apparatus can function solely as a platesetter or it can be incorporated directly into a lithographic printing press. In the latter case, printing may commence immediately after imaging and development, thereby reducing press set-up time considerably. The imaging apparatus can be configured as a flatbed recorder or as a drum recorder, with the imageable member mounted to the interior or exterior cylindrical surface of the drum. An example of an useful imaging apparatus is available as models of Kodak Trendsetter platesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio).

Imaging with infrared radiation can be carried out generally at imaging energies of at least 30 mJ/cm² and up to and including 500 mJ/cm², and typically at least 50 and up to and including 300 mJ/cm² depending upon the sensitivity of the imageable layer.

### Development and Printing

After thermal imaging, the elements are generally heated by radiation, convection (such as in an oven), contact with a heated surface (such as heated rollers), or immersion in a heated bath of water. The heating temperature is generally determined by the fog point of the imageable element. The fog point is defined as the lowest temperature, at a heating time of two minutes, required to render a thermally imageable element non-processable. When the imaged element is heated above the fog point, the non-exposed regions crosslink, and because they are not removable during development, no image is formed. Generally, the heating temperature is from about 120 to about 150° C. The time for heating can vary widely up to two minutes depending upon the method of heating that is to be used. Usually, the time of heating is from about 30 to about 90 seconds.

The imaged and heated elements are processed “off-press” using the single processing solution described herein. Processing is carried out for a time sufficient to remove predominantly only the non-exposed regions of the outermost imaged imageable layer to reveal the hydrophilic surface of the substrate, but not long enough to remove significant amounts of the exposed regions. The revealed hydrophilic surface repels inks while the exposed regions accept ink. Thus, the non-exposed regions to be removed are “soluble” or “removable” in the processing solution because they are removed, dissolved, or dispersed within it more readily than the regions that are to remain. The term “soluble” also means “dispersible”.

The processing solution both “develops” the imaged element by removing predominantly the non-exposed regions and also provides a protective layer or coating over the entire imaged and developed surface. In this aspect, the processing solution can behave somewhat like a gum that is capable of protecting the lithographic image on the printing plate against contamination or damage (for example, from oxidation, fingerprints, dust, or scratches).

There are generally two types of “gum” solutions known in the art: (1) a “bake”, “baking”, or “pre-bake” gum usually contains one or more compounds that do not evaporate at the usual pre-bake temperatures used for making lithographic printing plates, typically an anionic or nonionic surfactant, and (2) a “finisher” gum that usually contains one or more hydrophilic polymers (such as gum Arabic, cellulosic compounds, (meth)acrylic acid polymers, and polysaccharides) that are useful for providing a protective overcoat on a printing plate. The processing solution used in the practice of this invention could be considered a “pre-bake” gum.

By using this processing solution, the conventional aqueous alkaline developer compositions containing silicates or metasilicates are avoided. In some embodiments, processing solutions containing organic solvents are also avoided. If water-miscible solvents such as benzyl alcohol are present, they are present in an amount of up to 8 weight %. Other water-miscible solvents that may be present include but are not limited to, the reaction products of phenol with ethylene oxide and propylene oxide such as ethylene glycol phenyl ether (phenoxyethanol), esters of ethylene glycol and of propylene glycol with acids having six or fewer carbon atoms, and ethers of ethylene glycol, diethylene glycol, and of propylene glycol with alkyl groups having six or fewer carbon atoms, such as 2-ethoxyethanol and 2-butoxyethanol. A single organic solvent or a mixture of organic solvents can be used. By “water-miscible” we mean that the organic solvent or mixture of organic solvents is either miscible with water or sufficiently soluble in the processing solution that phase separation does not occur.

Moreover, one advantage of this invention is that once the processing solution is used in this manner, no separate rinsing step is necessary before using the resulting lithographic printing plate for printing. However, before printing, any excess processing solution may be removed from the lithographic printing plate by wiping or using a squeegee or a pair of nip rollers in an apparatus, followed by optional drying using any suitable drying means. The processing solution can be recycled and reused multiple times, replenished or regenerated as necessary, or used as single fresh samples that are discarded after a single use.

The processing solution may be provided in diluted or concentrated form. The amounts of components described below refer to amount in the diluted processing solution that is likely its form for use in the practice of the invention. However, it is to be understood that the present invention includes the use of concentrated processing solution and the amounts of various components (such as the anionic surfactants) would be correspondingly increased.

The processing solution used in this invention is an aqueous solution that generally has a pH greater than 6 and up to about 11, and typically from about 6.5 to about 11, or from about 7 to about 10.5, as adjusted using a suitable amount of a base. The viscosity of the processing solution can be adjusted to a value of from about 1.7 to about 5 cP by adding a suitable amount of a viscosity increasing compound such as a poly(vinyl alcohol) or poly(ethylene oxide).

Various components can be present in the processing solution to provide the development and gumming functions, except for those components specifically excluded below.

For example, some of the processing solutions have as an essential component, one or more anionic surfactants, although optional components (described below) can be present if desired. Useful anionic surfactants include those with carboxylic acid, sulfonic acid, or phosphonic acid groups (or salts thereof). Anionic surfactants having sulfonic acid (or salts thereof) groups are particularly useful. For example, anionic surfactants can include aliphates, abietates, hydroxyalkanesulfonates, alkanesulfonates, dialkylsulfosuccinates, alkyldiphenyloxide disulfonates, straight-chain alkylbenzenesulfonates, branched alkylbenzenesulfonates, alkylnaphthalenesulfonates, alkylphenoxypolyoxyethylenepropylsulfonates, salts of polyoxyethylene alkylsulfonophenyl ethers, sodium N-methyl-N-oleyltaurates, mono amide disodium N-alkylsulfosuccinates, petroleum sulfonates, sulfated castor oil, sulfated tallow oil, salts of sulfuric esters of aliphate alkylester, salts of alkylsulfuric esters, sulfuric esters of polyoxyethylene alkylethers, salts of sulfuric esters of aliphatic monoglucerides, salts of sulfuric esters of polyoxyethylenealkylphenylethers, salts of sulfuric esters of polyoxyethylenestyrylphenylethers, salts of alkylphosphoric esters, salts of phosphoric esters of polyoxyethylenealkylethers, salts of phosphoric esters of polyoxyethylenealkylphenylethers, partially saponified compounds of styrene-maleic anhydride copolymers, partially saponified compounds of olefin-maleic anhdyride copolymers, and naphthalenesulfonateformalin condensates. Alkyldiphenyloxide disulfonates (such as sodium dodecyl phenoxy benzene disulfonates), alkylated naphthalene sulfonic acids, sulfonated alkyl diphenyl oxides, and methylene dinaphthalene sulfonic acids) are particularly useful as the primary or “first” anionic surfactant. Several commercial examples are described in the Examples below. Such surfactants can be obtained from various suppliers as described in McCutcheon's Emulsifiers & Detergents, 2007 Edition.

Particular examples of such surfactants include but are not limited to, sodium dodecylphenoxyoxybenzene disulfonate, the sodium salt of alkylated naphthalenesulfonate, disodium methylene-dinaphthalene disulfonate, sodium dodecylbenzenesulfonate, sulfonated alkyl-diphenyloxide, ammonium or potassium perfluoroalkylsulfonate and sodium dioctylsulfosuccinate.

One or more anionic surfactants are generally present in an amount of at least 1 weight %, and typically from about 5 or from about 8 weight % and up to 45 weight %, or up to 30 weight % (% solids). In some embodiments, the one or more anionic surfactants may be present in an amount of from about 8 to about 20 weight %.

Two or more anionic surfactants (“first”, “second”, etc.) can be used in combination. In such mixtures, a first anionic surfactant, such as an alkyldiphenyloxide disulfonate, can be present generally in an amount of at least 1 weight % and typically from about 5 to about 20 weight %. A second surfactant can be present (same or different from the first anionic surfactant) in a total amount of at least 1 weight %, and typically from about 3 to about 30 weight %. Second or additional anionic surfactants can be selected from the substituted aromatic alkali alkyl sulfonates and aliphatic alkali sulfates. One particular combination of anionic surfactants includes one or more alkyldiphenyloxide disulfonates and one or more aromatic alkali alkyl sulfonates (such as an alkali alkyl naphthalene sulfonate).

The processing solutions useful in this invention may optionally include nonionic surfactants as described in [0029] or hydrophilic polymers described in [0024] of EP 1,751,625 (noted above), incorporated herein by reference. Particularly useful nonionic surfactants include Mazol® PG031-K (a triglycerol monooleate, Tween® 80 (a sorbitan derivative), Pluronic® L62LF (a block copolymer of propylene oxide and ethylene oxide), and Zonyl® FSN (a fluorocarbon), and a nonionic surfactant for successfully coating the gum onto the printing plate surface, such as a nonionic polyglygol. These nonionic surfactants can be present in an amount of up to 10 weight %, but at usually less than 2 weight %.

Other optional components of the gum include inorganic salts (such as those described in [0032] of U.S. Patent Application 2005/0266349, noted above), wetting agents (such as a glycol), a metal chelating agents, antiseptic agents, anti-foaming agents, ink receptivity agents (such as those described in [0038] of US '349), and viscosity increasing agents as noted above. The amounts of such components are known in the art. Other useful addenda include but are not limited to, phosphonic acids or polycarboxylic acids, or salts thereof that are different than the anionic surfactants noted above. Such polyacids can be present in an amount of at least 0.001 weight % and typically from about 0.001 to about 10 weight % (% solids), and can include but are not limited to, polyaminopolycarboxylic acids, aminopolycarboxylic acid, or salts thereof, [such as ethylenediaminetetraacetic acid (EDTA) or salts there of such as the sodium salt)], organic phosphonic acids and salts thereof, and phosphonoalkanetricarboxylic acids and salts thereof.

The processing solution can be applied to the imaged element by rubbing, spraying, jetting, dipping, immersing, slot die coating (for example see FIGS. 1 and 2 of U.S. Pat. No. 6,478,483 of Maruyama et al.) or reverse roll coating (as described in FIG. 4 of U.S. Pat. No. 5,887,214 of Kurui et al.), or by wiping the outer layer with the processing solution or contacting it with a roller, impregnated pad, or applicator containing the gum. For example, the imaged element can be brushed with the processing solution, or it can be poured onto or applied by spraying the imaged surface with sufficient force to remove the non-exposed regions using a spray nozzle system as described for example in [0124] of EP 1,788,431A2 (noted above) and U.S. Pat. No. 6,992,688 (Shimazu et al.). Still again, the imaged element can be immersed in the processing solution and rubbed by hand or with an apparatus.

The processing solution can also be applied in a processing unit (or station) in a suitable apparatus that has at least one roller for rubbing or brushing the imaged element while the processing solution is applied. By using such a processing unit, the non-exposed regions of the imaged layer may be removed from the substrate more completely and quickly. Residual processing solution may be removed (for example, using a squeegee or nip rollers) or left on the resulting printing plate without any rinsing step. Excess processing solution can be collected in a tank and used several times, and replenished if necessary from a reservoir. The processing solution replenisher can be of the same concentration as that used in processing, or be provided in concentrated form and diluted with water at an appropriate time.

Following processing, the resulting lithographic printing plate can be used for printing without any need for a separate rinsing step using water.

The resulting printing plate can also be baked in a postbake operation can be carried out, with or without a blanket or floodwise exposure to UV or visible radiation using known conditions. Alternatively, a blanket UV or visible radiation exposure can be carried out, without a postbake operation.

Printing can be carried out by applying a lithographic printing ink and fountain solution to the printing surface of the imaged and developed element. The fountain solution is taken up by the non-imaged regions, that is, the surface of the hydrophilic substrate revealed by the imaging and processing steps, and the ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged member to the receiving material. The imaged members can be cleaned between impressions, if desired, using conventional cleaning means.

The following examples are provided to illustrate the practice of the invention but are by no means intended to limit the invention in any manner.

### EXAMPLES

Unless otherwise noted below, the chemical components used in the Examples can be obtained from one or more commercial sources that would be apparent to a worker skilled in the art.

The components and materials used in the examples and analytical methods used in evaluation were as follows:

Byk® 307 is a polyethoxylated dimethyl polysiloxane copolymer that is available from Byk Chemie (Wallingford, Conn.) in a 25 wt. % xylene/methoxypropyl acetate solution.

Byk® 333 is a polyethoxylated dimethylpolysiloxane copolymer (Byk Chemie).

Cymel 303 is hexamethoxymethylmelamine that is available from Cytec Industries (West Paterson, N.J.).

Copolymer 4 contains 9.2 mol % recurring units derived from methacrylic acid, 34.82 mol % recurring units derived from benzyl methacrylate, and 55.98 mol % recurring units derived from methoxymethyl methacrylamide.

D11 dye is ethanaminium, N-[4-[[4-(diethylamino)phenyl][4-(ethylamino)-1-naphthalenyl]methylene]-2,5-cyclohexadien-1-ylidene]-N-ethyl-, salt with 5-benzoyl-4-hydroxy-2-methoxybenzenesulfonic acid (1:1) as supplied by PCAS (Longjumeau, France).

Diazo MSOS is 3-Methoxy-4-diazodiphenylamine octyl sulfate that is available from Diversitec (Fort Collins, Colo.).

Diazo MSPF6 is 2-Methoxy-4-aminophenyl diazonium hexafluorophosphate (Diversitec, Fort Collins, Colo.).

DOWANOL® PM is propylene glycol methyl ether (1-methoxy-2-propanol) that is available from Dow Chemical (Midland, Mich.).

Gum N1 (pH 9.4) is a solution containing 980 g of MX 1591 and 20 g of EDTA(Na)₄ salt. EDTA represents ethylenediaminetetraacetic acid.

Gum O1 (pH 8.7) is a solution containing 985 g of MX 1591 and 15 g of EDTA(Na)₄ salt.

IR Dye A has the following structure:

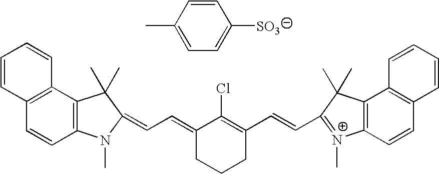

KF 1168 represents 3H-Indolium, 2-[2-[2-chloro-3-[(1,3-dihydro-1,3,3-trimethyl-2H-indol-2-ylidene)ethylidene]-1-cyclohexen-1-yl]ethenyl]-1,3,3-trimethyl salt with 4,5-dihydroxy-1,3-benzenedisulfonic acid (2:1) that is available from Honeywell (Seelze, Del.).

MX 1591 is a pre-bake gum (pH=4.2) that is available from Eastman Kodak Company (Rochester, N.Y.).

OLEC lightframe is an Olec PA93 photocell, diazo photopolymer bulb, wide band UV (350 to 420 nm), Olix A1131 Integrator, as supplied by Olec Corporation (Irvine, Calif.).

RC510 represents a washout storage gum that is available from Agfa Corporation (Ridgefield Park, N.J.).

Resole GP649D99 is a resole resin available from Georgia-Pacific (Atlanta, Ga.).

Rinse-Gum unit is a Quartz 850 RG plate processor, from NES Worldwide Inc. (Westfield, Mass.).

SP211 2-in-I developer/finisher is available from Eastman Kodak Company (Rochester, N.Y.).

TPCA represents terephthaldicarboxaldehdye that is available from Sigma-Aldrich (Saint Louis, Mo.).

Triazine represents TTT triazine S, as supplied by PCAS (Longjumeau, France) (CAS: 6542-67-2).

WDR3 represents 1,3-bis(2,3-dihydro-2,2-bis(((1-oxohexyl)oxy)methyl)-1H-perimidin-4-yl)-2,4-dihydroxy cyclobutenediylium bis (inner salt) that is available from Eastman Kodak Company (Rochester, N.Y.).

### Invention Example 1

The following imageable layer coating solution was prepared. About 12.93 g of Copolymer 4 was added to 213.37 g of Dowanol® PM, 9.30 g of water, and 9.30 g of 4-butyrolactone and dissolved. To this solution was added 2.78 g of Cymel® 303, 0.55 g of WDR3, 0.53 g of TPCA, 0.53 g of TTT triazine S, 0.13 g of D11, 0.12 g of a solution containing 10% of Byk® 333 in 1-methoxy-2-propanol, and 0.47 g of a solution containing 10% of Byk® 307 in 1-methoxy-2-propanol.

The coating solution was coated onto an electrochemically grained and anodized aluminum substrate that had been treated with poly(vinyl phosphonic acid) and the resulting imageable element was dried with hot air at 100° C. for about 2 minutes on a rotating drum to provide a dry coating weight of about 1.8 g/m².

The resulting imageable elements were imaged on a Kodak® Trendsetter 3244× image setter (Eastman Kodak, Burnaby, British Columbia, CA) at 830 nm IR laser at a power of 6.33 W and a range of drum speeds from 317 to 45 rpm (50 to 350 mJ/cm² exposure energy).

The imaged imageable element was preheated in a Heavy Duty Oven (Wisconsin Oven, East Troy, Wis.) at about 140° C. for about 1 minute and processed by hand in Gum N1 that was allowed to sit on the plate surface for 10 seconds followed by gentle agitation, repeating to a total time of 1 minute.

An image was obtained with a clean background. The minimum exposure energy to achieve maximum processed density was about 250 mJ/cm².

The imaged plate was mounted directly onto an A.B. Dick 9870 Duplicator Press (A.B. Dick, Niles, Ill.). The press was charged with Van Son Rubber Base black Ink (Van Son Ink, Mineola, N.Y.). An aqueous fountain solution contained about 23.5 ml/l (3 oz per gallon) Varn Litho Etch142W (Varn International, Addison, Ill.), and about 23.5 ml/l (3 oz per gallon) Varn PAR (alcohol substitute) in water. The plate was then wetted using a non-abrasive cloth filled with fountain solution. The press was started and the damping system engaged to further wet the plate with fountain solution. After a few revolutions, the inking system was engaged and about 200 copies were printed. Full ink density was reached at 25 sheets and the image quality was good.

### Invention Example 2

The procedure of Invention Example 1 was repeated except that the resulting imageable element was preheated in a Heavy Duty Oven at about 130° C. for about 1 minute and processed by hand in Gum O1 that was allowed to sit on the plate surface for 10 seconds followed by gentle agitation, repeating to a total time of 1 minute.

An image was obtained with a clean background. The minimum exposure energy to achieve maximum processed density was about 250 mJ/cm².

### Invention Example 3

The procedure of Invention Example 1 was repeated except that the resulting imageable element was imaged on an OLEC lightframe for 30 seconds at high intensity. The imaged imageable element was preheated in a Heavy Duty Oven at about 130° C. for about 1 minute and processed by hand in Gum N1 that was allowed to sit on the plate surface for 10 seconds followed by gentle agitation, repeating to a total time of 1 minute. An image was obtained with clean background.

### Invention Example 4

The following imageable layer coating solution was prepared. About 9.96 g of Copolymer 4 was added to 213.37 g of Dowanol® PM, 9.30 g of water, and 9.30 g of 4-butyrolactone and dissolved. To this solution were added 2.78 g of Cymel® 303, 0.55 g of WDR3, 0.53 g of TPCA, 3.50 g of Diazo MSPF6, 0.13 g of D11, 0.12 g of a solution containing 10% of Byk® 333 in 1-methoxy-2-propanol, and 0.47 g of a solution containing 10% of Byk® 307 in 1-methoxy-2-propanol.

The coating solution was coated onto an electrochemically grained and anodized aluminum substrate that had been treated with poly(vinyl phosphonic acid) and the resulting element was dried with hot air at 100° C. for about 2 minutes on a rotating drum to provide a dry coating weight of about 1.8 g/m².

Four samples of the resulting imageable element were imaged on a Kodak® Trendsetter 3244× image setter at 830 nm IR laser at a power of 6.33 W and a range of drum speeds from 317 to 45 rpm (50 to 350 mJ/cm² exposure energy).

Two imaged elements were preheated in a Heavy Duty Oven (Wisconsin Oven, East Troy, Wis.) at about 140° C. for about 1 minute and processed by hand in either Gum O1 or Gum N1, each being allowed to sit on the plate surface for 10 seconds followed by gentle agitation repeating to a total time of 1 minute. A third imaged imageable element was also preheated in a Heavy Duty Oven at about 120° C. for about 1 minute and processed by hand in RC510. A fourth imaged element was also preheated in a Heavy Duty Oven at about 120° C. for about 1 minute and developed in a rinse-gum unit at 1.5 ft/min (0.14 m/min) that was charged with RC510.

An image was obtained with clean background in each case. The minimum exposure energy to achieve maximum processed density was about 250 mJ/cm² for Gum O1, about 250 mJ/cm² for Gum N1, about 250 mJ/cm² for RC510 when hand-processed, and about 250 mJ/cm² for RC510 when processed with the rinse-gum unit.

### Invention Example 5

The following imageable layer coating solution was prepared. About 12.06 g of Copolymer 4 was added to 210.88 g of Dowanol® PM, 9.02 g of water, and 9.30 g of 4-butyrolactone and dissolved. To this solution were added 2.78 g of Cymel® 303, 3.65 g of a solution containing 24% of Resole in 1-methoxy-2-propanol, 0.55 g of WDR3, 0.53 g of TPCA, 0.53 g of TTT triazine S, 0.13 g of D11, 0.12 g of a solution containing 10% of Byk® 333 in 1-methoxy-2-propanol, and 0.47 g of a solution containing 10% of Byk® 307 in 1-methoxy-2-propanol.

The coating solution was coated onto an electrochemically grained and anodized aluminum substrate that had been treated with poly(vinyl phosphonic acid) and the resulting element dried with hot air at 100° C. for about 2 minutes on a rotating drum to provide a dry coating weight of about 1.8 g/m².

The resulting imageable elements were imaged on a KODAK® Trendsetter 3244× image setter at 830 nm IR laser at a power of 6.33 W and a range of drum speeds from 317 to 45 rpm (50 to 350 mJ/cm² exposure energy).

One sample of the imaged imageable element was preheated in a Heavy Duty Oven at about 130° C. for about 1 minute and processed by hand in Gum O1. Another sample of the imaged element was preheated at about 140° C. for about 1 minute and processed by hand in Gum N1 that was allowed to sit on the plate surface for 10 seconds followed by gentle agitation repeating to a total time of 1 minute. An image was obtained with clean background in each case. The minimum exposure energy to achieve maximum processed density was about 250 mJ/cm² for Gum O1, and about 200 mJ/cm² for Gum N1.

### Invention Example 6

The following imageable layer coating solution was prepared. About 12.93 g of Copolymer 4 was added to 213.37 g of Dowanol® PM, 9.30 g of water, and 9.30 g of 4-butyrolactone and dissolved. To this solution were added 2.78 g of Cymel® 303, 0.55 g of WDR3, 0.53 g of TPCA, 0.53 g of Diazo MSPF6, 0.13 g of D11, 0.12 g of a solution containing 10% of Byk® 333 in 1-methoxy-2-propanol, and 0.47 g of a solution containing 10% of Byk® 307 in 1-methoxy-2-propanol.

The coating solution was coated onto an electrochemically grained and anodized aluminum substrate that had been treated with poly(vinyl phosphonic acid) and the resulting element dried with hot air at 100° C. for about 2 minutes on a rotating drum to provide a dry coating weight of about 1.8 g/m².

Samples of the resulting imageable element were imaged on a Kodak® Trendsetter 3244× image setter at 830 nm IR laser at a power of 6.33 W and a range of drum speeds from 317 to 45 rpm (50 to 350 mJ/cm² exposure energy).

One imaged element was preheated in a Heavy Duty Oven at about 130° C. for about 1 minute and processed by hand in Gum O1. Another imaged element was preheated at about 140° C. for about 1 minute and processed by hand in Gum N1 that was allowed to sit on the plate surface for 10 seconds followed by gentle agitation repeating to a total time of 1 minute. An image was obtained with clean background in each case. The minimum exposure energy to achieve maximum processed density was about 300 mJ/cm² for Gum O1, and about 300 mJ/cm² for Gum N1.

### Invention Example 7

The following imageable layer coating solution was prepared. About 11.36 g of Copolymer 4 was added to 213.37 g of Dowanol® PM, 9.30 g of water, and 9.30 g of 4-butyrolactone and dissolved. To this solution were added 2.78 g of Cymel® 303, 0.55 g of WDR3, 0.53 g of TPCA, 2.10 g of Diazo MSPF6, 0.13 g of D11, 0.12 g of a solution containing 10% of Byk® 333 in 1-methoxy-2-propanol, and 0.47 g of a solution containing 10% of Byk® 307 in 1-methoxy-2-propanol.

The coating solution was coated onto an electrochemically grained and anodized aluminum substrate that had been treated with poly(vinyl phosphonic acid) and the resulting imageable element was dried with hot air at 100° C. for about 2 minutes on a rotating drum to provide a dry coating weight of about 1.8 g/m².

Samples of the resulting imageable element were imaged on a Kodak® Trendsetter 3244× image setter at 830 nm IR laser at a power of 6.33 W and a range of drum speeds from 317 to 45 rpm (50 to 350 mJ/cm² exposure energy). One imaged element was preheated in a Heavy Duty Oven at about 145° C. for about 1 minute and processed by hand in Gum O1. Another imaged element was preheated as above, and then processed by hand in Gum N1 that was allowed to sit on the plate surface for 10 seconds followed by gentle agitation repeating to a total time of 1 minute. An image was obtained with a clean background in each sample. The minimum exposure energy to achieve maximum processed density was about 250 mJ/cm² for Gum O1 and about 200 mJ/cm² for Gum N1.

### Invention Example 8

The following imageable layer coating solution was prepared. About 12.22 g of Copolymer 4 was added to 213.37 g of Dowanol® PM, 9.30 g of water, and 9.30 g of 4-butyrolactone and dissolved. To this solution was added 3.50 g of Cymel® 303, 0.55 g of WDR3, 0.53 g of TPCA, 0.53 g of TTT triazine S, 0.13 g of D11, 0.12 g of a solution containing 10% of Byk® 333 in 1-methoxy-2-propanol, and 0.47 g of a solution containing 10% of Byk® 307 in 1-methoxy-2-propanol.

The coating solution was coated onto an electrochemically grained and anodized aluminum substrate that had been treated with poly(vinyl phosphonic acid) and the resulting element dried with hot air at 100° C. for about 2 minutes on a rotating drum to provide a dry coating weight of about 1.8 g/m².

Samples of the resulting imageable element were imaged on a Kodak® Trendsetter 3244× image setter at 830 nm IR laser at a power of 6.33 W and a range of drum speeds from 317 to 45 rpm (50 to 350 mJ/cm² exposure energy).

One sample of the imaged element was preheated in a Heavy Duty Oven at about 145° C. for about 1 minute and processed by hand in Gum O1. Another sample was preheated as above, and then processed by hand in Gum N1 that was allowed to sit on the plate surface for 10 seconds followed by gentle agitation repeating to a total time of 1 minute. An image was obtained with clean background in each case. The minimum exposure energy to achieve maximum processed density was about 200 mJ/cm² for Gum O1, and about 200 mJ/cm² for Gum N1.

### Invention Example 9

The following imageable layer coating solution was prepared. About 11.34 g of Copolymer 4 was added to 213.37 g of Dowanol® PM, 9.30 g of water, and 9.30 g of 4-butyrolactone and dissolved. To this solution were added 4.38 g of Cymel® 303, 0.55 g of WDR3, 0.53 g of TPCA, 0.53 g of TTT triazine S, 0.13 g of D11, 0.12 g of a solution containing 10% of Byk® 333 in 1-methoxy-2-propanol, and 0.47 g of a solution containing 10% of Byk® 307 in 1-methoxy-2-propanol.

The coating solution was coated onto an electrochemically grained and anodized aluminum substrate that had been treated with poly(vinyl phosphonic acid) and the resulting element dried with hot air at 100° C. for about 2 minutes on a rotating drum to provide a dry coating weight of about 1.8 g/m².

Samples of the resulting imageable element were imaged on a Kodak® Trendsetter 3244× image setter at 830 nm IR laser at a power of 6.33 W and a range of drum speeds from 317 to 45 rpm (50 to 350 mJ/cm² exposure energy).

One sample of the imaged element was preheated in a Heavy Duty Oven at about 145° C. for about 1 minute and processed by hand in Gum O1. Another sample was preheated as above, and then processed by hand in Gum N1 that was allowed to sit on the plate surface for 10 seconds followed by gentle agitation repeating to a total time of 1 minute. An image was obtained with clean background in each case. The minimum exposure energy to achieve maximum processed density was about 250 mJ/cm² for Gum O1, and about 250 mJ/cm² for Gum N1.

### Invention Example 10

The following imageable layer coating solution was prepared. About 5.56 g of Copolymer 4 was added to 201.36 g of Dowanol® PM, 9.34 g of water, and 9.47 g of 4-butyrolactone and dissolved. To this solution were added 21.12 g of a solution containing 24% of Resole in 1-methoxy-2-propanol, 0.78 g of a solution containing 83% of Diazo MSOS in 90/10 water-4-butyrolactone, 0.95 g of KF1168, 0.58 g of IR dye A, 0.24 g D11, 0.12 g of a solution containing 10% of Byk® 333 in 1-methoxy-2-propanol, and 0.48 g of a solution containing 10% of Byk® 307 in 1-methoxy-2-propanol.

The coating solution was coated onto an electrochemically grained and anodized aluminum substrate that had been treated with poly(vinyl phosphonic acid) and the resulting element dried with hot air at 100° C. for about 2 minutes on a rotating drum to provide a dry coating weight: about 1.8 g/m². The imageable element was not developable to provide an image using any of Gum O1, Gum N1 or RC510, but it was developable using the “SP211” processing solution defined above.

The invention has been described in detail with particular reference to certain preferred embodiments thereof, but it will be understood that variations and modifications can be effected within the spirit and scope of the invention.

1. A method of making an image comprising:
A) using a laser providing infrared radiation, imagewise exposing a negative-working imageable element comprising a substrate having directly thereon an outermost negative-working imageable layer to provide exposed and non-exposed regions,
said outermost negative-working imageable layer comprising:
an acid generating compound that generates acid upon exposure to imaging infrared radiation,
an infrared radiation absorbing compound,
an acid activatable crosslinking agent that has at least two acid-activatable reactive groups, and
a polymeric binder that is capable of undergoing an acid-catalyzed condensation reaction with said crosslinking agent,
B) heating said imagewise exposed element at from about 120 to about 150° C. for up to two minutes, and
C) applying a single processing solution having a pH of from about 6 to about 11 to said imaged and heated element both: (1) to remove predominantly only said non-exposed regions, and (2) to provide a protective coating over all of said non-exposed and exposed regions of the resulting lithographic printing plate,
provided that when at least 40% of said acid activatable reactive groups are hydroxymethyl groups, said single processing solution comprises up to 8 weight % of a water-miscible organic solvent.

2. The method of claim 1 wherein said single processing solution has a pH greater than 7 and up to about 11 and comprises at least 1 weight % of one or more anionic surfactants.

3. The method of claim 1 wherein said single processing solution is essentially free of silicates, metasilicates, and organic solvents.

4. The method of claim 2 wherein said single processing solution further comprises at least 0.01 weight % of an organic phosphonic acid or polycarboxylic acid, or a salt of either acid that is different than said one or more anionic surfactants.

5. The method of claim 1 wherein said acid generating compound is a compound that forms a Brönsted acid by thermally initiated decomposition.

6. The method of claim 1 wherein at least 50% of said reactive groups in said acid activatable crosslinking agent are alkoxymethyl groups and the rest can be hydroxymethyl, epoxy, or vinyl ether groups bonded to an aromatic ring.

7. The method of claim 6 wherein said acid activatable crosslinking agent is a hexamethoxymethylmelamine.

8. The method of claim 1 wherein said polymeric binder is a polymer having reactive pendant groups that are carboxylic acid, sulfonamide, alkoxymethyl amide groups or a combination thereof.

9. The method of claim 1 wherein said imageable element is a lithographic printing plate precursor having an aluminum-containing substrate having a hydrophilic surface upon which said imageable layer is disposed.

10. The method of claim 1 wherein said imagewise exposure is carried out using imaging infrared radiation having a λₘₐₓof from about 750 to about 1200 nm.

11. The method of claim 1 wherein said single processing solution used in step C has a pH of from about 7.5 to about 10.

12. The method of claim 2 wherein at least one of said one or more anionic surfactants has a sulfonic acid group or salt thereof and is present in said single processing solution in an amount of from about 1 to about 45 weight %.

13. The method of claim 12 wherein at least one of said one or more anionic surfactants is an alkyldiphenyloxide disulfonate that is present in said single processing solution in an amount of from about 3 to about 30 weight %.

14. The method of claim 1 wherein said single processing solution comprises two or more anionic surfactants at least one of which is an alkyldiphenyloxide disulfonate that is present in an amount of from about 1 to about 30 weight %.

15. The method of claim 14 wherein said single processing solution comprises two or more different anionic surfactants one of which is an alkali alkyl naphthalene sulfonate that is present in an amount of from about 8 to about 20 weight %.

16. The method of claim 1 further comprising after step C, baking said lithographic printing plate at from about 160 to about 200° C. for up to two minutes.

17. The method of claim 1 further comprising:
D) mechanically removing excess single processing solution from said imaged and heated lithographic printing plate, with optional drying.

18. A method of lithographic printing comprising:
A) using a laser providing infrared radiation, imagewise exposing a negative-working lithographic printing plate precursor comprising a hydrophilic aluminum-containing substrate having directly thereon an outermost negative-working imageable layer to provide exposed and non-exposed regions,
said outermost negative-working imageable layer comprising:
an acid generating compound that generates acid upon exposure to imaging infrared radiation,
an infrared radiation absorbing compound,
an acid activatable crosslinking agent that has at least two acid-activatable reactive groups, and
a polymeric binder that is capable of undergoing an acid-catalyzed condensation reaction with said crosslinking agent,
B) heating said imagewise exposed element at from about 120 to about 150° C. for up to two minutes,
C) applying a single processing solution having a pH of from about 6 to about 11 to said imaged and heated precursor both: (1) to remove predominantly only said non-exposed regions, and (2) to provide a protective coating over all of said non-exposed and exposed regions of the resulting lithographic printing plate,
provided that when at least 40% of said acid activatable reactive groups are hydroxymethyl groups, said single processing solution comprises up to 8 weight % of a water-miscible organic solvent
D) mechanically removing excess single processing solution from said imaged and heated lithographic printing plate, with optional drying, and
E) contacting said lithographic printing plate with a lithographic printing ink, fountain solution, or both.
